(19) United States
(12) Patent Application Publication
(10) Pub. No.: US 2002/0155665 A1
(43) Pub. Date: Oct. 24, 2002

(54) Formation of notched gate using a multi-layer stack

(75) Inventors: Bruce B. Doris, Brewster, NY (US); Kevin M. Houlihan, S. Boston, MA (US); Samuel C. Ramac, Poughkeepsie, NY (US)

Correspondence Address: FREDERICK W. GIBB, III, MCGINN & GIBB, PLLC, 2568-A RIVA ROAD, SUITE 304, ANNAPOLIS, MD, 21401, US

(73) Assignee: INTERNATIONAL BUSINESS MACHINES CORPORATION,, ARMONK, NY

(21) Appl. No.: 09/841,531

(22) Filed: Apr. 24, 2001

(51) Int. Cl. H01L 29/80

(52) U.S. Cl. 438/279; 438/574; 257/268

(57) ABSTRACT

A field effect transistor device has a semiconductor substrate having a predetermined impurity concentration of a first conductivity type. Inpurity layers of a second conductivity type are formed spaced apart at the main surface of the semiconductor substrate. The impurity layers make up source/drain regions. A region between the impurity layers defines a channel region. A notch-shaped conductive layer is formed on the channel region. The notch-shaped conductive layer has an upper layer section longer than a lower layer section. The upper and lower layer sections are formed of at least two different materials, one being silicon-germanium layer with varying germanium content. The material of the lower layer section can be etched at a greater rate than the material of the upper layer section during a common etching process.

### BACKGROUND OF THE INVENTION

1. Field of the Invention

The present invention generally relates to semiconductor processing and, more particularly, to a MOS integrated circuit gate conductor layer having a notched gate structure using a multi-layer stack material.

2. Description of the Related Art

Fabrication of a metal oxide semiconductor field-effect transistor (“MOSFET”) device is well known. MOSFETs are generally manufactured by placing an undoped polycrystalline silicon (“polysilicon”) layer over a relatively thin silicon dioxide (“oxide”) layer. The polysilicon layer and the oxide layer are then patterned to form a gate conductor arranged upon a gate oxide with source/drain regions adjacent to and on opposite sides of the gate conductor. The gate conductor may be used to self-align impurities forwarded into the substrate on opposite sides of the gate conductor. The gate conductor and source/drain regions are then concurrently implanted with a dopant species. If the dopant species used is n-type, then the resulting MOSFET is an NMOS (“n-channel”) transistor device. Conversely, if the dopant species is p-type, then the resulting MOSFET is a PMOS (“p-channel”) transistor device. Integrated circuits typically use either n-channel devices exclusively, p-channel devices exclusively, or a combination of both on a single substrate. The combination of n-channel devices and p-channel devices on a single substrate is termed a complementary MOS (“CMOS”) device.

CMOS circuits offer numerous performance, reliability, design, and cost advantages over NMOS or PMOS circuits, and have become the dominant integrated circuit technology. One basic process for forming transistors for CMOS circuits only requires slight modification of the general technique for forming MOSFETs described above. In the basic CMOS process, a thin oxide layer is first formed upon a silicon substrate. The silicon substrate contains two active regions laterally separated by a field region. The field region includes an isolation structure, which may be formed by trench isolation or local oxidation of silicon (“LOCOS”) techniques. A single layer of undoped polysilicon is then deposited on the oxide layer. Gate structures are then formed within the active regions by patterning the layer of polysilicon and the layer of oxide. The resulting structures each include a gate conductor formed from the polysilicon layer and a gate oxide formed from the oxide layer.

These gate structures can be a T-shaped as taught in U.S. Pat. Nos. 5,089,863 and 5,272,100 or a notch-shaped as taught in U.S. Pat. No. 5,543,646, all of which are hereby incorporated by reference. One of the active regions, typically the region in which the p-channel device is to be formed, is covered with a masking layer of photoresist. N-type dopants are concurrently implanted into the other gate conductor and the adjacent semiconductor substrate. Such implantation serves both to dope the gate conductor and to form lightly-doped regions (“LDD”) in the silicon substrate. Oxide or silicon nitride spacers are then formed on the sidewalls of the uncovered gate structure. A second implant dose is then forwarded into the gate structure and the silicon substrate adjacent to the exposed lateral surfaces of the spacers. The second implant is done at a higher implant energy and dose than the first and creates source/drain regions within the silicon substrate. The process is then repeated for the p-channel transistor, except now p-type dopants are implanted.

In regards to gate structures having a notch form, physical dimension of this form of gate primarily determines an effective channel length of a MOSFET device, thus its resultant size. Previous constructions of notched poly-gates have included polysilicon with different grain sizes, phosphorus doped polysilicon, damaged polysilicon, and modifications to the gate stack etch process that creates narrower dimensions at the bottom of the poly-gate (see the referenced U.S. Pat. No. 5,543,646 discussed above). These methods are unacceptable for high performance CMOS devices that require smaller gate sizes.

When forming a notched gate using large grain polysilicon, this form of polysilicon etches faster than small grain polysilicon. Resultant constructions using these materials require an anistropic etching step with a lateral etch component. The referenced U.S. Pat. No. 5,543,646 discussed above includes such a method wherein the polysilicon layer has a grain size in a 1-2 micron range for the lower gate layer and a top polysilicon layer having grain sizes of 0.5 microns. Such constructions cannot provide faster operational characteristics necessary for future CMOS devices due to their inherent polysilicon gate depletion characteristics. Indeed, gate lengths (physical width of polysilicon gate) for state of the art CMOS devices are less than 0.1 microns. These dimensions are progressively getting smaller in requisite designs.

The range of grain sizes for both the fast etching as well as the slower etching polysilicon films in the prior art are much larger than current high performance CMOS gate dimensions, which are approximately 500 angstroms and smaller. Current CMOS processes include polysilicon grain sizes that are relatively smaller compared to the polysilicon line width. This reduces gate depletion by effectively thickening the gate oxide. This reduces gate capacitance and results in fewer ionic states at a given Ioff.

One of the mechanisms responsible for polysilicon gate depletion is large polysilicon grain size. This is caused by dopant diffusion in polysilicon that takes place predominantly by grain boundary diffusion. Larger poly-grains result in less grain boundaries in a polysilicon gate, thus preventing dopants from diffusing to the bottom of the polysilicon gate where depletion occurs. Since small grain polysilicon is needed to reduce polysilicon depletion in high performance CMOS gates, current methods cannot achieve the necessary operational characteristics for future high performance CMOS devices.

In addition, photolithography used to define the narrow gate dimensions for current CMOS is strongly affected by roughness of the polysilicon, which is directly proportional to grain sizes. Polysilicon films having larger grains have increased roughness. Required dose and focus for lithography vary as a function polysilicon thickness. The roughness in the polysilicon is typically caused by a local variation in thickness of anti-reflective coatings and resist layers during processing. Thus, the ideal lithographic focus and dose cannot be achieved for a rough polysilicon surface, which leads to non-uniform widths for resist profiles. This in turn translates to large across chip line width variation (ACLV), which is a figure of merit used to qualify gate formation as to all the gate structures having similar size during fabrication. In view of this problem, notched gate constructions using different grain sizes cannot achieve requisite fast operational requirements for CMOS devices.

Another form of notched gate construction known in the art uses a phosphorus doped lower layer and an intrinsic polysilicon upper layer. Since the phosphorus doped layer etches faster than the intrinsic polysilicon layer and because of the requisite lateral etch component, the notched gate profile may be achieved without altering the etch process. While potentially suitable for an NFET device which requires N-type doping in the gate, this process is not suitable for a PFET device, which cannot accept N-type doping in the lower portion where maximum activation is required. As stated above, one of the concerns for high performance CMOS devices is polysilicon gate depletion. If appreciable amounts of phosphorus are introduced into the PFET gate, then overall P-type active concentration is reduced, thereby degrading the depletion characteristics of the PFET. Significant amounts of phosphorus (about 1×10¹⁹ atoms/cm³ and greater) are needed to enhance the etch rate of polysilicon. Since maximum gate activation for PFETs is required for high performance CMOS. This form of construction cannot meet the operational characteristics of faster and smaller CMOS devices. Another form of notched gate construction known in the art involves damaging the lower portion of the polysilicon gate layer with ion implantation. The implant conditions usually are capable of damaging the lower portion of the gate polysilicon, which has a wide distribution of ion energies. The damaged layer etches faster compared to undamaged regions, wherein etching has a lateral etch component. To create damage in the lower portion of the gate material, the peak of the implant must be very close to the gate oxide. Since there is always energy spread or “straggel” in the ion energy distribution, there is no way to prevent the gate oxide from also being damaged. Thus, use of this method cannot achieve the high performance characteristics necessary for CMOS devices where gate oxides are now becoming thinner than 20 angstroms.

Another form of notched gate construction known in the art involves changing the etch characteristics during the gate stack etch process. This method has inherent control problems caused by isotropic plasmas that are used, which have non-uniform distributions of ion directions and energies. This causes the height of the notch structure and line width to have significant ACLV variation both within a wafer and from wafer to wafer. This form of gate construction using stack etching using an isotropic etch cannot achieve the demanding line width tolerances required for high performance CMOS gates. Thus, this method of construction is unsuitable for current and future CMOS devices.

In view of above problems, there is need in the art for smaller notched gate structures that have a smaller effective gate length that are produced using lithographic processing compatible with conventional methods.

### SUMMARY OF THE INVENTION

In view of the foregoing and other problems, disadvantages, and drawbacks of the conventional notched gated structures in MOSFET devices, the present invention has been devised, and it is an object of the present invention to provide a structure and method for creating notched gate structures that provide reduced gate depletion characteristics by forming the notched gate with improved materials.

Thus, the invention comprises a field effect transistor device having a semiconductor substrate with a predetermined impurity concentration of a first conductivity type, impurity layers of a second conductivity type (the impurity layers form source/drain regions), a region between the impurity layers defining a channel region; and a notch-shaped conductive layer formed on the channel region. An insulating layer is interposed between the channel and notch-shaped conductive layer. The notch-shaped conductive layer has an upper layer section longer than a lower layer section. The upper and lower layer sections are formed of at least two disparate materials, one of which is silicon-germanium. The material of the lower layer section can be etched at a greater rate than the material of the upper layer section during a common etching process. This solves the problems mentioned in the background and allows very small notched gate stacks to be formed.

### BRIEF DESCRIPTION OF THE DRAWINGS

The foregoing and other objects, aspects and advantages will be better understood from the following detailed description of a preferred embodiment(s) of the invention with reference to the drawings, in which:

FIGS. 1a, 1b, 1c, 1d and 1e show a sequenced method of forming the notched shaped gate structure of a FET of the present invention; and

FIGS. 2a, 2b, 2c and 2d show the various forms of the notched shaped gate structure of the present invention.

### DETAILED DESCRIPTION OF PREFERRED EMBODIMENTS OF THE INVENTION

Formation of a notched gate structure in MOSFETs using two or more disparate materials that include silicon-germanium materials overcomes problems associated with prior notched gate constructions. Specifically, use of these materials in a notched gate structure enables a smaller and faster CMOS device to be made by minimizing across-chip-line variation (ACLV). Since these disparate materials have differing etch rates, a precision and uniform notch gate structure results during fabrication, thereby minimizing ACLV characteristics by eliminating complications caused during the etch process. In addition, since the silicon-germanium material may have grain sizes that are smaller when compared to gate dimensions, and have an etch rate that is faster than that of polysilicon, problems associated with roughness in association with attendant ACLV degradation and large grain sizes are minimized. Additionally, there is no degradation in gate depletion caused by phosphorus implanted when constructing a PFET gate, and there is no ACLV degradation caused by isotropic etching, as there is conventionally.

The present invention can be applied to the NMOS or PMOS type transistors. Additionally, the notched gate structure formed by use of the invention can be used in MOS transistors formed on the single substrate, an epitaxial substrate, or silicon-on-insulator (SOI) substrate. The present invention is also applied to a compound semiconductor besides the silicon semiconductor.

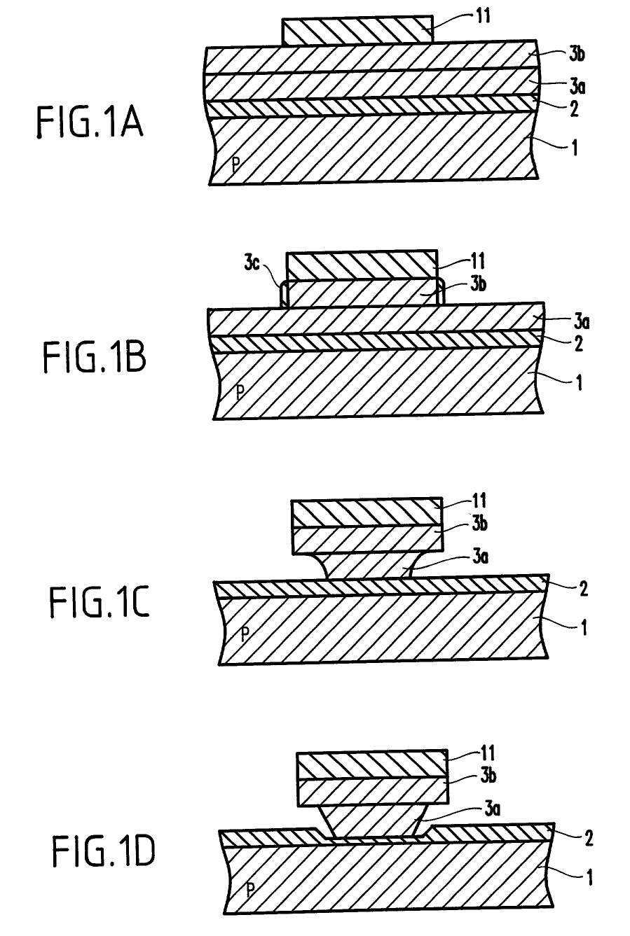

Referring now to FIGS. 1a-d, an exemplary sequenced method and resultant structures are shown according to the present invention. With reference to FIG. 1a, the P-type substrate 1 is shown with a silicon dioxide insulating layer 2 and multiple types of etchant materials in layers 3a and 3b from which the notched gate conductor layer is formed on the silicon dioxide layer 2. Item 11 is a common masking material. Two or more different materials form the polystack gate conductor layers 3a and 3b. These materials etch at differing rates during the same reactive ion etching (RIE) conditions. Since the etch rate is proportional to the layer type, the composition of the layer type can be made uniform with abrupt transitions.

In FIG. 1b, the upper gate material 3b is etched using mask 11 and protective spacers 3c are formed. The structure is etched in FIG. 1c, resulting in a notched-shaped gate.

The multiple layers, that include polystack layers 3a and 3b, can be more than two layers and can have varying concentrations of germanium, thus having different silicon-germanium compositions. For example, if three layers are used, a first layer may have 15% germanium while the second layer may have 7% germanium and the third layer may contain less germanium than the previous two layers. In general, a multiple layer structure may be used where the germanium concentration of the silicon-germanium layering decreases from the bottom of the stacked layer to the top of the stack.

For example, a lower layer 3a may be polysilicon-germanium and the upper layer 3b may be polysilicon (poly-Si). Since the etch rate of the poly-SiGe is faster than the etch rate of the polysilicon, a notched gate is formed with-no alteration in the etch process. In other words, a highly anisotropic etch may be used throughout the etch. Since lateral etching occurs even in highly anisotropic etches, the lower layer has a faster etch rate material and becomes narrow compared to the top section of the gate stack. The fact that the etch characteristics remain unchanged throughout the etch is why the ACLV characteristics do not change with respect to standard gate stack etch processes. In addition, the polysilicon-germanium layer may have the same grain size as the polysilicon layer. Also, it is not necessary to use phosphorus doping in the PFET device, or to damage the lower portion of the stack material by ion implantation. Therefore, use of silicon-germanium materials to form a notched gate precludes degrading the ACLV characteristics during fabrication, minimizes gate depletion and does not result in gate oxide damage that commonly occurs in conventional CMOS devices.

Another form of the lower layer 3a is poly-SiGe having higher Ge concentration compared to the upper layer 3b that is also poly-SiGe layer. Since the higher concentration poly SiGe layer has a higher etch rate than the lower Ge concentration poly SiGe layer, a notched gate structure is produced.

This embodiment has the same advantages as afforded by the previous embodiment. Specifically, a highly anisotropic etch may be used and not altered through the entire etch to produce a notched gate. This etching process results in exceptional ACLV characteristics compared to isotropic etch processes. Additionally, grain sizes of lower and upper layers are small compared to the gate dimensions so that roughness is minimal, thereby further enhancing the ACLV and the gate depletion characteristics. As stated above, no phosphorus doping is required, which causes degradation for polysilicon depletion regions in PFETS. Also, no damage is caused to the gate oxide by an implantation processes with unwanted dopant material.

As shown in FIG. 1d, layers 3a and 3b can form a single layer of poly-SiGe having increased Ge concentration from the top of the layer to the bottom of this layer in a modulated form of concentration. Since the high concentration portion of the poly-SiGe layer etches faster than the lower Ge concentration portion of the poly-SiGe layer, a notched gate structure results. As stated in the previous two embodiments, a highly anisotropic etch may be used throughout the etch process. Grain sizes may be relatively small so as not to alter the lithography-process thereby further enhancing the ACLV characteristics as well as the gate depletion characteristics. This leads to improved gate depletion characteristics and good gate oxide qualities compared to prior notch gate designs.

Additionally, to define the structural components of a FET, FIG. 1e is provided in accordance with the present invention that comprises a semiconductor substrate 1, a source region 4a and a drain region 4b formed on the main surface of the semiconductor substrate 1. A gate electrode 3 is formed on the main surface of the semiconductor substrate. The FET has a gate electrode 3 that is comprised of multiple layers that include at least two layers 3a and 3b.

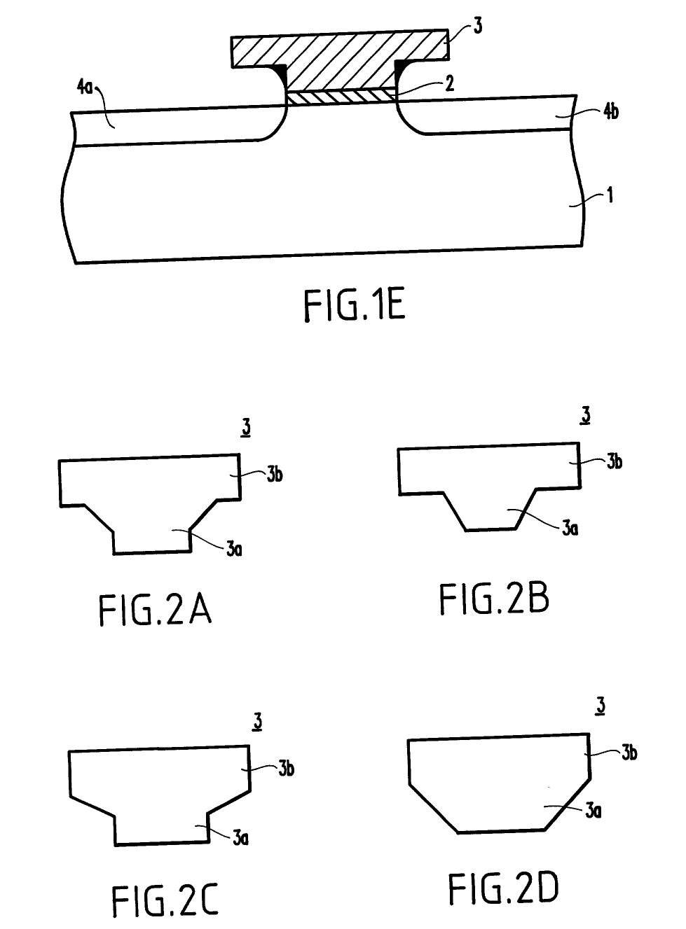

The method for making a field effect transistor having a notched gate formed electrode 3 includes preparing the various forms of semiconductor substrate as discussed above. The substrate surface can have a predetermined impurity concentration of a certain N or P-type conductivity type. Next, well known techniques of forming an insulating gate oxide layer on the main surface of the semiconductor substrate is effectuated. A first layer 3a is deposited on the gate oxide insulating layer 2, using one of the three embodiments listed above. Next, at least a second layer designated as second layer 3b is deposited on the first layer 3a. Layer 3b can be a material such as polysilicon, amorphous silicon-germanium, and polysilicon-germanium with a second concentration of germanium. Next, RIE etching is performed wherein the first layer 3a and second layer 3b are formed into a notched-shaped layer that result in the shapes as shown in FIG. 2a-2d. The following step includes a well known doping step where ions of the opposite conductivity type are implanted to a first impurity concentration in the main surface of the semiconductor substrate. The next step includes heat treatment of the doped semiconductor substrate. Doping of ions of the opposite conductivity type to a second impurity concentration can then be effectuated. The second impurity concentration is higher than the first impurity concentration on the main surface of the semiconductor substrate 1. Next, heat treatment of the doped semiconductor substrate is performed, such that the field effect transistor now has first source-drain regions and second source-drain regions. The region between the first source-drain regions defines a first channel region.

The method can also include forming side walls 3c on one side surface and the other side surface of the second layer 3b by insulating silicon nitride layers during a portion of the RIE etching step (FIG. 1b). Moreover, the first layer 3a and the second layer 3b can be doped by well known source-drain doping processes. The silicon-germanium layers 3a, 3b achieve activation (or requisite conductivity) by this source drain doping process, which is typically boron for a PFET structure and either phosphorus or arsenic for an NFET structure.

Various forms of a resultant notched conductive layer 3a and 3b for a FET are shown in FIG. 2a-2d. In these forms of the gate electrode 3, the shaped conductive layer has an upper section 3b and a lower section 3a, wherein the upper section is longer than the lower section and the length of the lower section adjacent the insulating layer is substantially equal to or shorter than the length of the channel region at the main surface of the semiconductor substrate. In the embodiments of FIGS. 2c and 2d, the lower section 3a includes a section having tapered sidewalls and a section having vertical sidewalls. In FIGS. 2c and 2d, the sidewalls of the lower section are tapered along their entire length.

Additionally, during NMOS integration, a doped interfacial gate poly/dielectric interface can reduce gate depletion and reduce the inversion thickness of the gate conductive layer structure, thus synergistically improving device performance with reduced channel lengths of notched poly gates.

The inventive notched gate structure 3 is compatible with current and future CMOS devices and provides a smaller and faster notch gated MOSFET. Specifically, previous notched gate structures make use of properties of large grain polysilicon that etches faster than small grain polysilicon. The present invention uses specially selected silicon-germanium materials in various embodiments that improve ACLV characteristics in such MOSFET devices. Also, prior to the invention, use of polysilicon alone for notch gate structures results in large grains that cause polysilicon depletion which degrades performance and causes ACLV degradation due to the roughness of these large grains. The invention herein obviates these problems. Additionally, conventional processes have used phosphorus doped polysilicon to facilitate etching at a faster rate compared to intrinsic polysilicon, wherein the phosphorous doping may be acceptable for the NFET gate, but CMOS devices that have PFET gates as well, are degraded by such phosphorus doping. This degradation is even more severe if the phosphorus is placed in the lower portion of the gate structure, where polysilicon depletion effects are pronounced as described above. Since phosphorus doping effectively reduces the active concentration of P-type doping in the PFET, prior methods of constructing notched gates reduce gate activation for the PFET, which are unsuitable for high performance CMOS devices. The invention also requires no isotropic etching to form the notched gate, thus ACLV degradation caused by isotropic etching is eliminated. Finally, the invention requires no ion implantation to create damaged regions to form the gate as described above.

While the invention has been described in terms of preferred embodiments, those skilled in the art will recognize that the invention can be practiced with modification within the spirit and scope of the appended claims.

What is claimed is:

1. A field effect transistor comprising:
a substrate having source and drain regions;
a gate insulator above said substrate;
a notch-shaped gate conductor above said gate insulator, said notch-shaped gate conductor comprising at least two layered sections, including an upper layer and a lower layer,
wherein said layered sections comprise at least two different materials, one of which comprises silicon-germanium, and
wherein said lower layer has a higher etch rate than said upper layer.

2. The field effect transistor according to claim 1, wherein said upper layer comprises polysilicon-germanium and said lower layer is selected from a group consisting of amorphous silicon and polysilicon.

3. The field effect transistor in claim 2, wherein said amorphous silicon and polysilicon are devoid of germanium.

4. The field effect transistor according to claim 1, wherein said lower layer and said upper layer comprise polysilicon-germanium (poly-SiGe) having concentrations of germanium that increase along a depth of said upper layer section and said lower layer section.

5. The field effect transistor according to claim 4, wherein an increase in said concentrations of germanium is directly proportional to a depth between a bottom of said lower layer and a top of said upper layer.

6. The field effect transistor in claim 1, wherein said upper layer and said lower layer comprise materials capable of being simultaneously etched.

7. A field effect transistor comprising:
a substrate having source and drain regions;
a gate insulator above said substrate;
a notch-shaped gate conductor above said gate insulator, said notch-shaped gate conductor comprising at least two layered sections, including an upper layer and a lower layer,
wherein said upper layer comprises polysilicon and said lower layer comprises amorphous silicon, and
wherein said lower layer has a higher etch rate than said upper layer.

8. The field effect transistor according to claim 7, wherein said upper layer section comprises polysilicon-germanium.

9. The field effect transistor in claim 8, wherein said amorphous silicon is devoid of germanium.

10. The field effect transistor in claim 7, wherein said upper layer and said lower layer comprise materials capable of being simultaneously etched.

11. A method for making a field effect transistor having a notch-shaped gate conductor, said method comprising:
forming a gate insulator above a substrate;
depositing a gate conductor material over said gate insulator, wherein said gate conductor material comprises at least two layered sections, including an upper layer and a lower layer, said layered sections comprising at least two different materials, one of which comprises silicon-germanium, and said lower layer having a higher etch rate than said upper layer;
etching said gate conductor material through a mask to define a notch-shaped gate conductor;
doping said notch-shaped gate conductor and said substrate, to make said notch-shaped gate conductor conductive, and to form source and drain regions in said substrate.

12. The method in claim 11, wherein said upper layer comprises polysilicon-germanium and said lower layer is selected from a group consisting of amorphous silicon and polysilicon.

13. The method in claim 12, wherein said amorphous silicon and polysilicon are devoid of germanium.

14. The method in claim 11, wherein said lower layer and said upper layer comprise polysilicon-germanium (poly-SiGe) having concentrations of germanium that increase along a depth of said upper layer section and said lower layer section.

15. The method in claim 14, wherein an increase in said concentrations of germanium is directly proportional to a depth between a bottom of said lower layer and a top of said upper layer.

16. The method in claim 11, wherein said etching of said gate conductor material comprises a single etching process.

17. A method for making a field effect transistor having a notch-shaped gate conductor, said method comprising:
forming a gate insulator above a substrate;
depositing a gate conductor material over said gate insulator, wherein said gate conductor material comprises at least two layered sections, including an upper layer and a lower layer, said upper layer comprising polysilicon, said lower layer comprising amorphous silicon, and said lower layer having a higher etch rate than said upper layer;
etching said gate conductor material through a mask to define a notch-shaped gate conductor; and
doping said notch-shaped gate conductor and said substrate, to make said notch-shaped gate conductor conductive, and to form source and drain regions in said substrate.

18. The method in claim 17, wherein said upper layer section comprises polysilicon-germanium.

19. The method in claim 18, wherein said amorphous silicon is devoid of germanium.

20. The method in claim 17, wherein said etching of said gate conductor material comprises a single etching process.
